(19) United States
(12) Patent Application Publication
(10) Pub. No.: US 2019/0115719 A1
(43) Pub. Date: Apr. 18, 2019

(54) SEMICONDUCTOR LIGHT-EMITTING ELEMENT AND SEMICONDUCTOR LIGHT-EMITTING DEVICE

(71) Applicant: SHARP KABUSHIKI KAISHA, Sakai City (JP)

(72) Inventors: SHIGETOSHI ITO, Sakai City (JP); TERUYUKI OOMATSU, Sakai City (JP); KAZUAKI KANEKO, Sakai City (JP)

(21) Appl. No.: 16/147,752

(22) Filed: Sep. 30, 2018

(30) Foreign Application Priority Data
Oct. 16, 2017 (JP) 2017-200535

(51) Int. Cl. H01S 5/024; H01S 5/022; H01S 5/40

(52) U.S. Cl. CPC H01S 5/02469; H01S 5/02296; H01S 5/02292; H01S 5/02212; H01S 5/02268; H01S 5/02272; H01S 5/4025

(57) ABSTRACT

A semiconductor light-emitting element includes: a base made of metal; a cap mounted on the base; a semiconductor laser chip mounted over an upper surface of the base; and a lead through which the semiconductor laser chip is supplied with electric power. The base has a notch provided in a region of a bottom surface thereof. The lead is disposed so as to extend vertically through the base in the region of the base where the notch is provided. The semiconductor laser chip is mounted over a region of the base that is free from the notch. An upper end of the lead and the semiconductor laser chip are housed in an internal space surrounded by the cap and the base.

### BACKGROUND

### 1. Field

The present disclosure relates to a can-type semiconductor light-emitting element and a semiconductor light-emitting device including the same.

### 2. Description of the Related Art

In the field of various industries, semiconductor light-emitting elements mounted with semiconductor laser chips or high-power LED chips are currently used. A widely-used example of such a semiconductor light-emitting element is a can-type semiconductor light-emitting element such as that disclosed, for example, in Japanese Unexamined Patent Application Publication No. 2006-135219.

FIG. 1 shows a conventional can-type semiconductor light-emitting element 500. The semiconductor light-emitting element 500 includes a base 501, a block 502, a sub-mount 503, and a semiconductor laser chip 504. The base 501 is a plate member made of metal. The block 502 is made of metal and provided on the base 501 so as to protrude. The semiconductor laser chip 504 is mounted lateral to the block 502 with the sub-mount 503 interposed between the block 502 and the semiconductor laser chip 504. A laser beam that is emitted from an end face of the semiconductor laser chip 504 is directed upward in a vertical direction with respect to the base 501.

Leads 507 are fixed to the base 501 by glass hermetic sealing to secure insulation and airtightness. Note, however, that a lead (not illustrated) that is electrically in common with a stem is fixed so as to be directly connected to the stem. The leads 507 and the semiconductor laser chip 504 are connected as appropriate by a wire for current introduction. It should be noted that in order to avoid complicated illustration, FIG. 10 omits to illustrate the wire.

A cap 505 is bonded to the base 501 by electric resistance welding or the like in order to cover the semiconductor laser chip 504 for hermetic sealing. The cap 505 is provided with a window 506, made of glass, through which to take out output light from the semiconductor laser chip 504. The window 506 is bonded to the cap 505 for airtightness. Typically, the planar shape of the base 501 is a circle.

Such can-type semiconductor light-emitting elements are composed of packages made of metal and therefore provide good radiation performance. Further, can-type semiconductor light-emitting elements allow use of established technologies such as bonding of metals by welding or the like, low-melting-point glassing of window glass to a metallic cap, and glass hermetic sealing. For this reason, they are widely used, as they are comparatively low in packaging cost and capable of rigorously hermetically sealing laser chips.

Another possible configuration of a semiconductor light-emitting element is a package in which a block 502 such as that shown in FIG. 10 is not used but a laterally-facing semiconductor laser chip or the like is mounted directly on a base (metal plate) (Japanese Unexamined Patent Application Publication No. 7-162092 and Japanese Unexamined Patent Application Publication No. 5-129711). In such a package structure, the direction of emission of light from the semiconductor laser chip is parallel to the base. Therefore, there is known a semiconductor light-emitting element configured to, using a mirror that reflects emitted light upward, emit light perpendicularly to the base as a result.

Such a type of semiconductor light-emitting element has a shorter pathway of heat radiation to a bottom surface of the base, as the semiconductor laser chip is mounted sideways over the base. In comparison with the semiconductor light-emitting element of FIG. 10, which radiates heat from the base via the protruding block, such a type of semiconductor light-emitting element is expected to provide better radiation performance.

Semiconductor light-emitting elements are expected to be developed as various light sources such as light sources for 3D printers, light sources for molding and processing, light sources for projectors, and light sources for lighting by increasing light output from semiconductor laser chips to the watt class or higher. In the field of such applications, there is a demand for an increase in laser output from individual packages through improvement in heat radiation from the packages. Furthermore, there is also a demand for utilization of a plurality of integrated packages as a further high-power light source by gathering output light with an optical system.

These applications require a semiconductor light-emitting element to operate with high input power, making it necessary to efficiently let out heat generated from the semiconductor light-emitting element. For that purpose, the semiconductor light-emitting element is inevitably attached to a heat sink.

FIG. 11 is a diagram schematically showing a cross-section of a heat sink 601 with the conventional can-type semiconductor light-emitting element 500 shown in FIG. 10 attached to the heat sink 601.

The semiconductor light-emitting element 500 has its leads 507 extending from the bottom surface of the base. For this reason, attaching the semiconductor light-emitting element 500 to the heat sink 601 makes it necessary to bore holes 602 through the heat sink 601 and run the leads 507 through the holes 602. At this time, the leads 570 are covered with tubular insulating members 603 to be electrically insulated from the heat sink 601. The leads 507 are electrically connected to a mounting substrate, wires, and the like with solder 604 or the like, whereby a pathway of current introduction to the semiconductor light-emitting element 500 is formed. It should be noted that in order to avoid complicated illustration, FIG. 11 omits to illustrate members (wiring members such as a mounting substrate and covered wires) to which the leads 507 are connected.

A configuration of such a heat sink 601 makes it necessary to provide the holes 602, a recess 605, and the like in a region of the semiconductor light-emitting element 500 near the lower side of the semiconductor laser chip 504 that is supposed to contribute to heat radiation most. The recess 605 is a space for connecting the leads 507 by soldering. Providing the heat sink 601 with the holes 602 and the recess 605 impairs a pathway of heat radiation from the semiconductor laser chip 504 to directly below and makes it not easy to sufficiently secure an area of contact between a bottom surface of the semiconductor light-emitting element 500 and the heat sink 601. This poses big problems in achieving improvement in heat radiation of the semiconductor light-emitting element 500.

Furthermore, the complicated shape of the heat sink 601 makes manufacture and assembly of the heat sink 601 troublesome. Simply increasing the size of the whole package may lead to an increase in area of contact of the semiconductor light-emitting element 500 with the heat sink 601. However, increasing the package size of the semiconductor light-emitting element 500 of course inhibits miniaturization of a device and, in particular, poses an impediment to the foregoing application of high-density integration. That is, a decrease in integration density of a plurality of semiconductor light-emitting elements makes it more difficult to gather output light with an optical system, and this goes against the purpose of utilizing a high-power laser beam.

The semiconductor light-emitting element described in Japanese Unexamined Patent Application Publication No. 7-162092 is structured such that leads extends from a bottom surface of the base, as is the case with the semiconductor light-emitting element 500 shown in FIG. 10. Therefore, this semiconductor light-emitting element still has the aforementioned problem of attachment to a heat sink and cannot sufficiently bring out the merit of improvement in heat radiation.

The semiconductor light-emitting element described in Japanese Unexamined Patent Application Publication No. 5-129711 is structured such that a frame is made around a metal plate and leads are disposed to run through the frame. In this structure, a flat metal plate is exposed at a bottom surface of the package and the leads do not protrude downward from the package. This eliminates the problem of attachment of the semiconductor light-emitting element to a heat sink, and heat generated during operation of the semiconductor laser chip can be radiated through the metal plate to directly below. This brings about a great improvement in radiation effect.

However, the semiconductor light-emitting element described in Japanese Unexamined Patent Application Publication No. 5-129711 is not a can-type package in the first place, and the drawing of the leads from the semiconductor light-emitting element does not involve the use of a glass hermetic sealing technology. It is conceivable that the semiconductor light-emitting element of Japanese Unexamined Patent Application Publication No. 5-129711 may be configured such that the leads are sealed with resin or the like; however, such resin sealing is more insufficient to inhibit gas from leaking outside than sealing of the leads by a hermetic sealing technology. Therefore, for example, use of this packaging technology for a blue laser poses a problem such as aged deterioration of the laser chip.

Further, when the frame is made of ceramic or the like in the semiconductor light-emitting element of Japanese Unexamined Patent Application Publication No. 5-129711, the package for achieving airtight sealing is so expensive that the cap cannot be seal-attached by highly productive electric resistance welding unlike in the case of a conventional can type. That is, the semiconductor light-emitting element of Japanese Unexamined Patent Application Publication No. 5-129711 cannot enjoy the merits of a can-type semiconductor light-emitting element such as comparatively good heat radiation, low packaging and manufacturing costs, and the capability of rigorously hermetically sealing a laser chip.

### SUMMARY

It is desirable to provide a semiconductor light-emitting element and a semiconductor light-emitting device that make it possible to improve radiation performance in using a can-type semiconductor light-emitting element attached to a heat sink.

According to an aspect of the disclosure, there is provided a semiconductor light-emitting element including: a base made of a metal plate; a cap, mounted on the base, that has a window made of an optically transparent member; a semiconductor laser chip mounted over an upper surface of the base; and a lead for supplying electric power to the semiconductor laser chip. The base has a notch provided in a region of a bottom surface thereof. The lead is disposed so as to extend vertically through the base in the region of the base where the notch is provided. The semiconductor laser chip is mounted over a region of the base that is free from the notch. A lower end of the lead is located above the bottom surface of the base. An upper end of the lead and the semiconductor laser chip are housed in an internal space surrounded by the cap and the base.

According to an aspect of the disclosure, there is provided a semiconductor light-emitting device including: a heat sink; and a semiconductor light-emitting element mounted on the heat sink. The semiconductor light-emitting element is the semiconductor light-emitting element described above.

### BRIEF DESCRIPTION OF THE DRAWINGS

FIG. 1 is a perspective view showing a can-type semiconductor light-emitting element according to Embodiment 1;

FIG. 2 is a perspective view showing an internal structure of the semiconductor light-emitting element of FIG. 1 with its cap removed;

FIG. 3 is a cross-sectional view of the internal structure of the semiconductor light-emitting element of FIG. 1 as taken along line III-III of FIG. 1;

FIG. 4 is a cross-sectional view schematically showing a configuration of a semiconductor light-emitting device according to an example of Embodiment 1;

FIG. 5 is a graph showing results of evaluation of the thermal resistance of semiconductor light-emitting elements according to examples of the present disclosure;

FIG. 6 is a cross-sectional view schematically showing a configuration of a semiconductor light-emitting device according to another example of Embodiment 1;

FIG. 7 is a perspective view schematically showing a configuration of a semiconductor light-emitting device according to Embodiment 2;

FIG. 8 is a diagram schematically showing an example of a light-gathering system including the semiconductor light-emitting device of Embodiment 2;

FIG. 9A is a top view of a semiconductor light-emitting element according to Embodiment 3 with its cap removed;

FIG. 9B is a bottom view of the semiconductor light-emitting element according to Embodiment 3;

FIG. 10 is a cross-sectional view showing a conventional can-type semiconductor light-emitting element; and

FIG. 11 is a diagram schematically showing a state where the conventional can-type semiconductor light-emitting element is attached to a heat sink.

### DESCRIPTION OF THE EMBODIMENTS

### Embodiment 1

### Structure of Semiconductor Light-Emitting Element

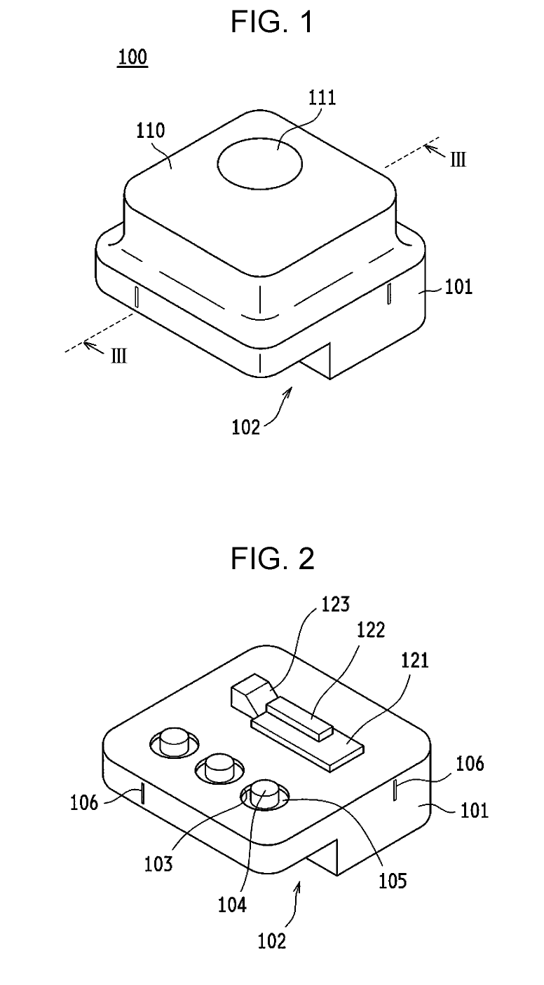

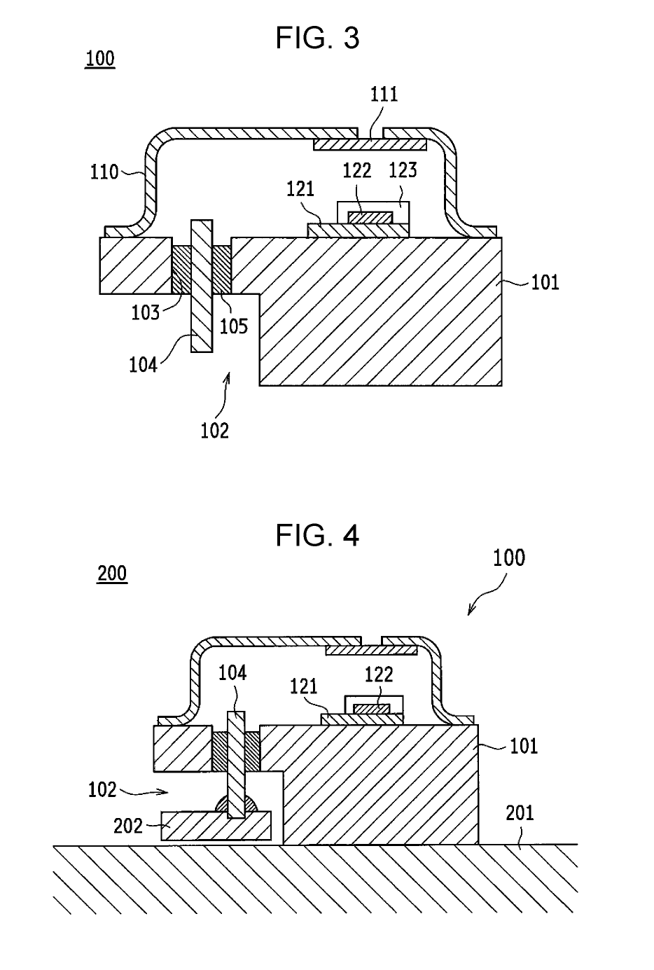

Embodiments of the present disclosure are described in detail below with reference to the drawings. FIG. 1 is a perspective view showing a can-type semiconductor light-emitting element 100 according to Embodiment 1, and FIG. 2 is a perspective view showing an internal structure of the semiconductor light-emitting element 100 according to Embodiment 1 with its cap 110 removed. Further, FIG. 3 is a cross-sectional view taken along line III-III of FIG. 1.

The semiconductor light-emitting element 100 includes a base 101 and a cap 110. The base 101 is made of a metal plate and has an upper surface (chip-mounting surface) that is a substantially flat surface. The cap 110 is mounted on the upper surface of the base 101 by being bonded near the surrounding areas of the base 101. This causes the semiconductor light-emitting element 100 to have an internal space that is formed by the base 101 and the cap 110. In Embodiment 1, when seen in a plan view, the base 101 has a substantially square shape having rounded corners. The cap 110 has a window 111 formed in an upper surface thereof. The window 111 is made of glass.

The base 101 has a notch 102 provided in a bottom surface thereof so as to extend along one side surface. For this reason, the base 101 is thinner in thickness in a region where the notch 102 is provided than in other regions. Meanwhile, the base 101 has a top side including a flat surface where the cap 110 is bonded, and is configured such that the internal space of the semiconductor light-emitting element 110 can be sealed by the cap 110 being bonded by electric resistance welding or the like.

In the base 101, the notch 102 is provided with a plurality of through holes 103. A lead 104 made of metal is inserted in each of the through holes 103 so as to protrude vertically in a thickness direction of the base 101. The through holes 103 are arranged side by side along a side of the substantially square base 101, more specifically a side corresponding to the side surface along which the notch 102 is provided. A space between each of the through holes 103 and the corresponding lead 104 is filled with glass 105, and the lead 104 is fixed to the base 101 while having good insulating properties with the base 101.

The lead 104 has a substantially linear shape and has its lower end located above the bottom surface of the base 101. Placing the semiconductor light-emitting element 100 on a flat surface of a heat sink or the like brings only the bottom surface of the thick region of the base 101 into contact with the flat surface, thus causing the notch 102 to form a space between a flat surface of the notch 102 and the base 101. At this time, since the lower end of the lead 104 is located above the bottom surface of the base 101, the lower end of the lead 104 is located in the space and does not inhibit the semiconductor light-emitting element 100 from being placed on a flat surface of a heat sink or the like. Further, in a plan view of the semiconductor light-emitting element 100, the lead 104 falls within the base 101 without running off from an outer edge of the base 101.

The lead 104 has its upper end located in the internal space surrounded by the base 101 and the cap 110. In the internal space of the semiconductor light-emitting element 100, a sub-mount 121 is placed on the upper surface of the base 101 and a semiconductor laser chip 122 is mounted on the sub-mount 121. When seen in a plan view, the semiconductor laser chip 122 is disposed in a region where the base 101 is great in thickness (i.e. a region circumventing the notch 102). Further, the semiconductor laser chip 122 has a waveguide longitudinal direction that is substantially parallel to the upper surface of the base 101 and substantially parallel to the direction in which the through holes 103 are arranged.

Furthermore, a mirror 123 is placed over the upper surface of the base 101 so as to face a light emission surface of the semiconductor laser chip 122. This causes an emitted laser beam from the light emission surface of the semiconductor laser chip 122 to be reflected upward by the mirror 123 and released to the outside through the window 111.

The lead 104 is connected via a metal wire such as a gold wire or a gold ribbon to an electrode pad provided on the semiconductor laser chip 122 or the sub-mount 121. This forms a configuration in which the semiconductor laser chip 122 can be supplied with electric power through the lead 104. The foregoing configuration is achieved by the lead 104 having its upper end located above the upper surface of the base 101 and being present in the internal space of the semiconductor light-emitting element 100. Further, since the semiconductor light-emitting element 100 of Embodiment 1 is configured such that the direction in which a plurality of the leads 104 are arranged and the waveguide longitudinal direction of the semiconductor laser chip 122 (i.e. the direction of a laser guided wave inside a laser) are substantially parallel to each other, the metal wires via which the electrode pads and the leads 104 are connected can be prevented from interfering with an optical path of a laser beam that is emitted from the semiconductor laser chip 122. It should be noted that in order to avoid complicated illustration, FIGS. 2 and 3 omit to illustrate these metal wires.

The base 101 may have its side surface provided with a marker 106 that serves as a benchmark for a position of light emission from the semiconductor light-emitting element 100. This marker 106 allows a user of the semiconductor light-emitting element 100 to easily recognize the position of light emission (i.e. an apparent position of a luminous point). The marker 106 may be one printed on the base 101 or may be a depression or a protrusion provided in or on the side surface of the base 101.

### Manufacturing Method

The following describes a method for manufacturing a semiconductor light-emitting element 100 according to Embodiment 1.

The base 101, which is made of metal, can be molded by using a well-known technique for manufacturing a base of a can package. As a material of the base 101, a material selected from among publicly-known can package materials such as a material composed mainly of iron and a material composed mainly of copper can be used as appropriate. As the material of the base 101, the material composed mainly of iron has the merit of making welding of the cap 110 easy and the material composed mainly of copper has the merit of being superior in radiation performance.

Further, the base 101 is not limited to one made of a material that is uniform in its entirety, but a so-called laminated material can alternatively be used. Use of press working for the molding of the base 101 makes it possible to manufacture the base 101 with high mass-producibility and at low cost. Meanwhile, use of brazing or welding for the molding of the base 101 makes it possible to select a plurality of right materials for the right parts of the base 101 and make up the base 101 of a complex combination. Normally, the base 101 has its surface plated with gold, nickel, palladium, or the like.

The lead 104, which is made of metal, is fixed to the base 101 by a glass hermetic technique while being airproofed. By being plated with gold or nickel, the lead 104 allows a metal wire and solder to make a good connection and can achieve excellent electrical conductivity.

The semiconductor laser chip 122 is mounted on the sub-mount 121 and mounted over the upper surface of the base 101 with the sub-mount 121 interposed between the base 101 and the semiconductor laser chip 122. The sub-mount 121 can be made of ceramic composed mainly of aluminum nitride, silicon carbide, or the like. Alternatively, the sub-mount 121 may be made of metal such as copper or CuW or may be made of another publicly-known material. Note, however, that the present disclosure is not limited to the foregoing configuration. The semiconductor laser chip 122 may be mounted directly on the base 101. In this case, heat generated from the semiconductor laser chip 122 can be let out directly to the base 101, so that there is improvement in radiation performance. In a case where the sub-mount 121 is made of a conducting material such as metal or the semiconductor laser chip 122 is mounted directly on the base 101, one of the electrode pads on the semiconductor laser chip 122 is electrically connected to the base 101. In this case, the lead 104 directly connected to the base 101 can be used as a connection terminal to the outside of the element.

The semiconductor laser chip 122 can be fixed to the base 101 or the sub-mount 121 by using a publicly-known technique such as soldering or conductive paste bonding. In so doing, a publicly-known bonding material can be used. In FIG. 2, the upper surface of the base 101 is totally flat, and the sub-mount 121 is mounted on the flat surface. However, the present disclosure is not limited to this. A depression or a protrusion can be provided as appropriate in or on the surface of the base 101 insofar as the radiation of heat to the bottom surface of the base 101 is not greatly inhibited, and the sub-mount 121 (or the semiconductor laser chip 122) can be mounted on this depression or protrusion.

A usable example of the mirror 123 is one obtained by coating a surface of a prism-shaped glass member with a highly reflective film. Such a mirror 123 can be fixed to the base 101 by an adhesive, soldering, or the like. Instead of being constituted by the aforementioned glass member, the mirror 123 can be made of a publicly-known mirror material such as a semiconductor material or a metal material. Furthermore, the mirror 123 can be formed integrally with the base 101 as an inclined surface of the depression or protrusion formed in or on the base 101.

The connection between the electrode pad provided on the semiconductor laser chip 122 or the sub-mount 121 and the lead 104 by the metal wire precedes the bonding of the cap 110 to the base 101.

As the cap 110, a cap according to a publicly-known technology that is used as a cap of a can-type package can be used. Such a cap 110 is hermetically attached by an established technology to a glass member that is to become the window 111, is mass-producible, and is inexpensive. It is desirable, for the purpose of high productivity, low cost, secure sealing, that the cap 110 be attached to the base 101 by well-known electric resistance welding. The following is an outline of a technique for attaching the cap 110 to the base 101 by an electric resistance welding method. The base 101 is fixed to an energizable stage. The cap 110 is set on an energizable jig. A welded part that is a flange surrounding a bottom surface of the cap 110 is put between the jig and the stage and pressurized, and a pulsed current is passed, whereby the welded part is heated and welded.

The electric resistance welding method is low in cost because instantaneous completion of welding and an extremely short lead time. Further, a welding apparatus is constituted by a smaller number of movable parts that require precise positioning as in the case of seam welding or laser welding, and the welding apparatus can also be made lower in cost. Note, however, that the electric resistance welding method is not the only method for attaching the cap 110 to the base 101. It is possible to use another bonding method such as seam welding, laser welding, or soldering.

Structure of Semiconductor Light-Emitting Device

The following describes a semiconductor light-emitting device according to the present disclosure. The semiconductor light-emitting device here is a device that is used in the form of a unit including a semiconductor light-emitting element and a heat sink on which the semiconductor light-emitting element is placed. FIG. 4 is a cross-sectional view schematically showing a configuration of a semiconductor light-emitting device 200 according to an example of Embodiment 1.

The semiconductor light-emitting device 200 has a structure in which the aforementioned semiconductor light-emitting element 100 is placed on a heat sink 201. In the semiconductor light-emitting element 100, the lead 104 is disposed so that its lower end does not protrude from the bottom surface of the base 101 (so that the lower end of the lead 104 is located above the bottom surface of the base 101). For this reason, the semiconductor light-emitting element 100 makes it possible to bring substantially the whole bottom surface of the base 101 excluding the notch 102 into contact with the heat sink 201.

Since the lower end of the lead 104 is located above the bottom surface of the base 101, the lead 104 can be electrically connected to an external wiring member 202 in a space that is formed by the notch 102. Note here that the wiring member 202 can be an appropriate member such as a connection substrate or a covered electric wire. The lead 101 can be electrically connected to the wiring member 202 by using a publicly-known technique such as soldering or socket connection as appropriate. FIG. 4 shows a state where the wiring member 202 floats above the heat sink 201, and this means a configuration in which there occurs no short-circuit between the wiring member 202 and the heat sink 201. That is, since the heat sink 201 is made of a highly exoergic metal material, it is necessary to secure insulation between the wiring member 202 and the heat sink 201. The insulation may be secured by placing an insulating member between the wiring member 202 and the heat sink 201.

The semiconductor light-emitting device 200 allows the semiconductor light-emitting element 100 to operate with the bottom surface of the base 101 of the semiconductor light-emitting element 100 substantially wholly in close contact with a flat surface of the heat sink 201. It should be noted that the heat sink 201 is not limited to any particular outer shape in the present disclosure but can have an outer shape selected as appropriate according to a situation in which the semiconductor light-emitting device 200 is used.

In the semiconductor light-emitting element 100, the semiconductor laser chip 122 and the sub-mount 121 are placed parallel to the upper surface of the base 101. For this reason, heat is favorably radiated from the semiconductor laser chip 122 to the base 101. Not only that, when seen in a plan view of the semiconductor light-emitting element 100, the semiconductor laser chip 122 and the sub-mount 121 are placed in such a position as not to overlap the notch 102 of the base 101. This causes the semiconductor light-emitting device 200 to be structured such that a region near the lower side of the semiconductor laser chip 122 that is supposed to contribute to heat radiation most is in direct contact with the heat sink 201. Further, in the region below the semiconductor laser chip 122, there is no through hole formed for the supply of electric power to the semiconductor light-emitting element 100. This structure allows heat to be extremely favorably radiated from the semiconductor laser chip 122 to the heat sink 201.

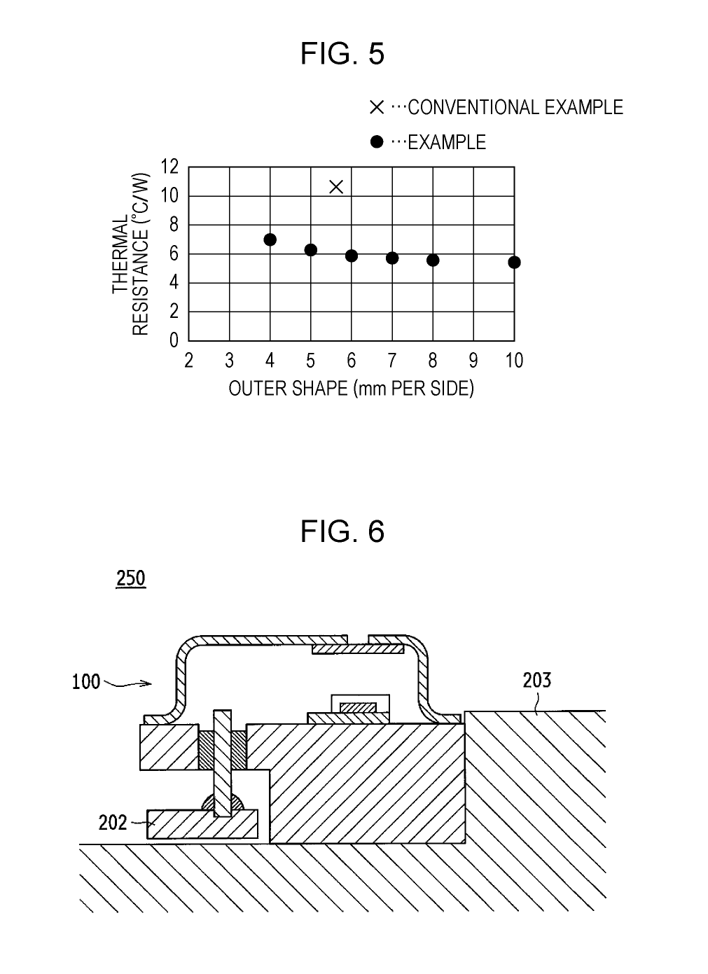

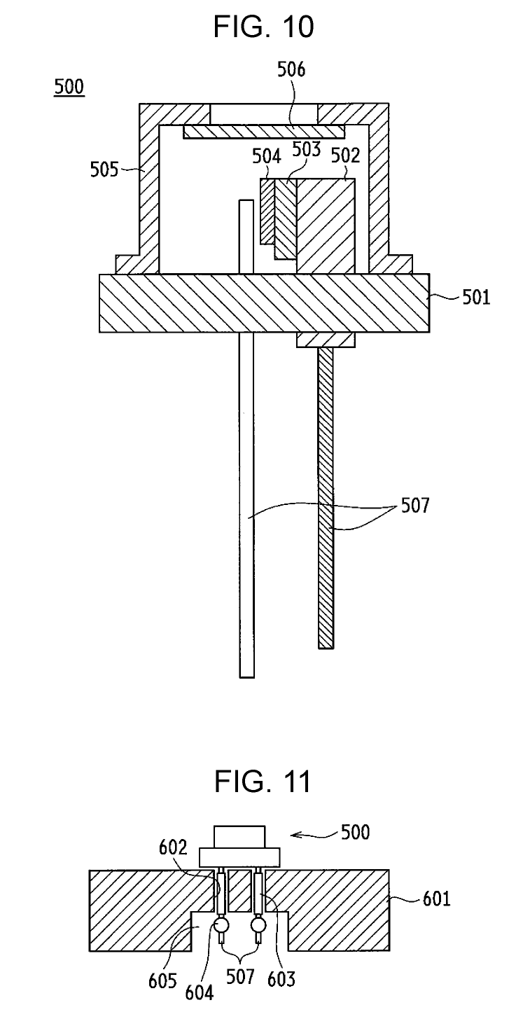

FIG. 5 is a graph showing results of evaluation of the thermal resistance of semiconductor light-emitting elements according to examples of the present disclosure. The semiconductor light-emitting elements according to the examples were identical in structure to the aforementioned semiconductor light-emitting element 100. Further, the semiconductor laser chip 122 was a semiconductor laser chip made of a nitride semiconductor and had a waveguide width of 30 μm. The sub-mount 121 was made of aluminum nitride, and the semiconductor laser chip 122 was placed on the sub-mount 121 junction down. The base 101 was made of copper. Further, FIG. 5 also shows, as a conventional example, a result of evaluation of the thermal resistance of the conventionally-packaged semiconductor light-emitting element shown in FIG. 10. Under the foregoing conditions, the semiconductor light-emitting elements according to the examples had their bases 101 in outer shapes measuring 4 to 8 and 10 mm, respectively, per side. Further, the semiconductor light-emitting element according to the conventional example was normally packaged with a diameter of 5.6 mm.

The thermal resistance of the example whose outer shape measures 6 mm per side takes on a value of a little under 6° C./W, and a comparison with the value 10.5° C./W of thermal resistance of the conventional example clearly shows remarkable improvement in thermal resistance. Further, once the size of a base 101 measures approximately 5 mm or larger per side, a further increase in package size only leads to a gentle decrease in thermal resistance.

The semiconductor light-emitting element 100 according to Embodiment 1 exhibits extremely good radiation performance in comparison with the conventional can-type semiconductor light-emitting element. This makes it possible to make the light output of the semiconductor laser chip 122 used several times higher than that of a conventional one. Furthermore, in terms of sealing of the semiconductor laser chip 122, there is no difference from a normal can-type package, as a hermetic sealing technology, resistance welding, a metallic cap can be used. This makes an extremely rigorously cutoff from the outside air possible at low manufacturing cost and makes it possible to enjoy such a merit of a can-type semiconductor light-emitting element that the semiconductor laser chip 122 does not deteriorate.

FIG. 6 is a cross-sectional view schematically showing a configuration of a semiconductor light-emitting device 250 according to another example of Embodiment 1.

The semiconductor light-emitting device 250 shown in FIG. 6 includes a heat sink 203 instead of including the heat sink 301 shown in FIG. 4. The heat sink 203 has an upper surface that is not flat but has a step. The semiconductor light-emitting device 250 has its semiconductor light-emitting element 100 placed such that not only the bottom surface of the base 101 but also a part of a side surface of the base 101 are in contact with the heat sink 203. This structure of the semiconductor light-emitting device 250 makes the heat sink 203 more complex in shape than the heat sink 201 shown in FIG. 4, but brings about an increase in area of contact between the semiconductor light-emitting element 100 and the heat sink 203 and thereby allows further improvement in radiation performance.

### Embodiment 2

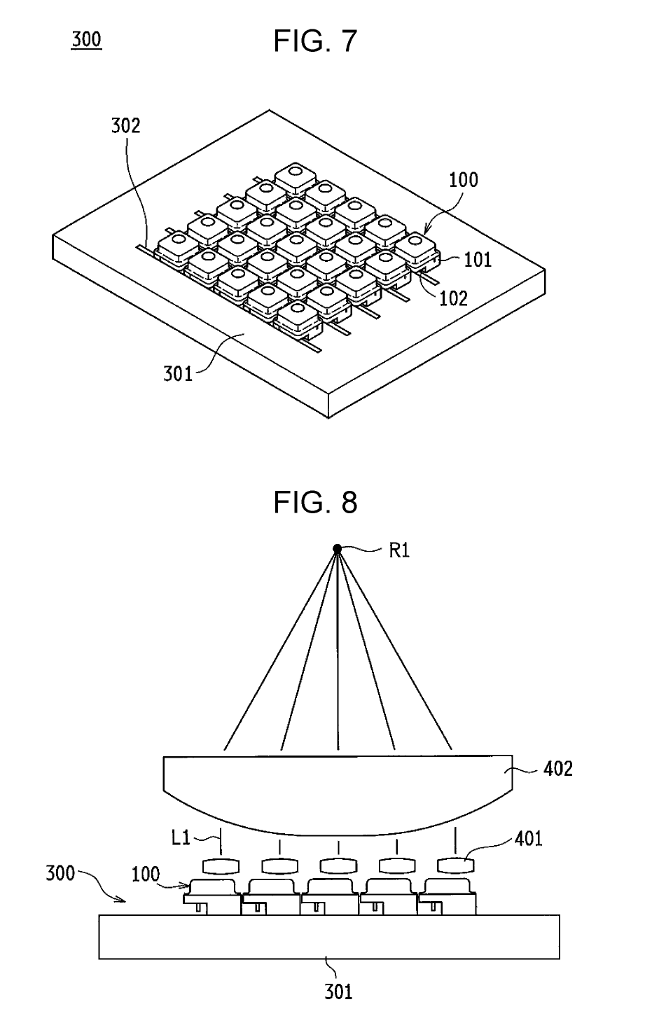

Embodiment 2 describes, with reference to the perspective view of FIG. 7, a semiconductor light-emitting device 300 obtained by integrating a plurality of semiconductor light-emitting elements 100 described in Embodiment 1.

The semiconductor light-emitting device 300 is structured such that the plurality of semiconductor light-emitting elements 100 are arranged in a two-dimensional matrix on a heat sink 301. Note, however, that the present disclosure is not limited to this structure. The semiconductor light-emitting device 300 may alternatively be structured such that the plurality of semiconductor light-emitting elements 100 are arranged in a line. Note here that since the semiconductor light-emitting elements 100 each have a substantially square shape when seen in a plan view and the leads 104 of the semiconductor light-emitting elements 100 fall within the base 101 without running off from an outer edge of the base 101, the semiconductor light-emitting elements 100 can be densely arranged. Semiconductor light-emitting elements 100 arranged in an identical line of the matrix are all arranged in the same direction, i.e. so that the aforementioned notches 102 are aligned in a straight line. Moreover, a wiring member 302 is placed in a space formed by the notches aligned in a straight line, and the semiconductor light-emitting elements 100 are connected to this wiring member 302. This allows each of the semiconductor light-emitting element 100 to be supplied with electric power through the wiring member 302.

In the semiconductor light-emitting device 300 thus structured, the semiconductor light-emitting elements 100 can be densely arranged with the heat sink 301 in close contact with the bottom surface of the base 101 of each of the semiconductor light-emitting elements 100. Further, the semiconductor light-emitting elements 100 can be arranged so that their luminous points are placed at identical pitches. In this case, a covered electric wire or the like can be used as the wiring member 302; however, in view of a connection to the semiconductor light-emitting elements 100, it is desirable that the wiring member 302 be a wiring substrate having a desired wiring pattern.

Since the semiconductor light-emitting device 300 according to Embodiment 2 includes semiconductor light-emitting elements 100 described in Embodiment 1, hermetic sealing of the semiconductor laser chips is extremely favorably done. This prevents the semiconductor laser chips from deteriorating due to incomplete sealing of the semiconductor light-emitting elements 100, allowing the semiconductor light-emitting device 300 to have superior reliability. Further, it is possible to use, as each of the semiconductor light-emitting elements 100, one selected through characteristic evaluation after packaging. This makes it possible to prevent defective items from being mixed in even when the plurality of semiconductor light-emitting elements 100 are integrated into the semiconductor light-emitting device 300. Thus, the semiconductor light-emitting device 300, which is an integrated package, can be prevented from being defective as a whole, and the semiconductor light-emitting device 300 can be made superior in producibility. Therefore, the semiconductor light-emitting device 300 can be manufactured at a high yield rate and can achieve a highly-reliable integrated package at low cost.

Further, as noted in Embodiment 1, the semiconductor light-emitting elements 100 are far superior in radiation performance that conventional can-type semiconductor light-emitting elements. For this reason, the semiconductor light-emitting device 300 can more densely integrate the semiconductor light-emitting elements 100 while securing passage of electricity to the semiconductor laser chip than a device obtained by integrating conventional can-type semiconductor light-emitting elements. This allows the semiconductor light-emitting device 300 to minimize the spread of luminous points as the whole integrated package.

As an example, when the semiconductor light-emitting elements 100 of the semiconductor light-emitting device 300 each have a size measuring approximately 6 mm per side, it is possible to output 5 watts of blue light from each of the semiconductor light-emitting elements 100, and when arranged in a 5×5 matrix, the semiconductor light-emitting elements 100 can produce a laser output of 125 W as a whole. At this time, the luminous points fall within an area measuring only 24 mm per side; for example, one-point focusing is made possible with a condensing lens having a diameter of 40 mm, and a compact laser output exceeding 100 W can be attained. Such a compact and high-power semiconductor light-emitting device 300 is suitable as a light source for applications such as a laser processing apparatus, a laser welding machine, a laser soldering machine, a 3D printer, a projector. Meanwhile, in the case of use of conventional 5.6 mm diameter semiconductor light-emitting elements, which are vastly inferior in thermal resistance, only approximately 2 watts of blue light can be outputted from each of the semiconductor light-emitting elements. The difference is clear.

FIG. 8 is a diagram schematically showing an example of a light-gathering system including the semiconductor light-emitting device 300 of Embodiment 2. Each of the semiconductor light-emitting elements 100 of the semiconductor light-emitting device 300 is provided with a corresponding collimating lens 401 that turns a laser beam emitted from the semiconductor light-emitting element 100 into parallel light L1. The collimating lenses 401 emit lasers to A condensing lens 402 is disposed to face a laser emission side of the collimating lenses 401. Rays of parallel light L1 emitted from the collimating lens 401 are condensed by the condensing lens 402 into a light-gathering region R1, which is a single spot or a narrow region.

Note here that in order to make the light-gathering system compact, it is important to reduce the aperture of the condensing lens 402 by reducing the area of a region of distribution of the luminous points of the semiconductor light-emitting device 300.

The semiconductor light-emitting device 300 of Embodiment 2 favorably allows heat to be radiated from each of the semiconductor light-emitting elements 100 toward the heat sink 301 and can densely arrange the semiconductor light-emitting elements 100 while securing a space for wiring through which the semiconductor light-emitting elements 100 are supplied with electric power. For this reason, the semiconductor light-emitting device 300 can achieve a compact and high-power laser light source.

### Embodiment 3

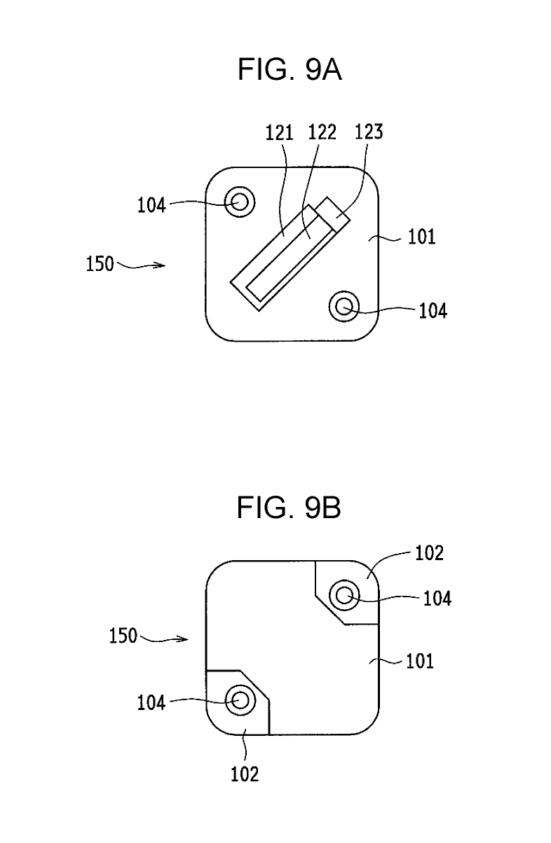

Embodiment 3 describes, with reference to FIGS. 9A and 9B, a semiconductor light-emitting element 150 differing in structure from the semiconductor light-emitting element 100 described in Embodiment 1. FIG. 9A is a top view of the semiconductor light-emitting element 150 with its cap removed, and FIG. 9B is a bottom view of the semiconductor light-emitting element 150. Although the semiconductor light-emitting element 150 has a cap attached to the upper surface of the base 101, the state of attachment of the cap in the semiconductor light-emitting element 150 is the same as that of the semiconductor light-emitting element 100 and therefore is not described here.

The following are respects in which the semiconductor light-emitting element 150 differs from the semiconductor light-emitting element 100 described in Embodiment 1. The other components of the semiconductor light-emitting element 150 are the same as those of the semiconductor light-emitting element 100.

(1) On the upper surface of the base 101, a set of the sub-mount 121, the semiconductor laser chip 122, and the mirror 123 is placed so that the waveguide longitudinal direction of the semiconductor laser chip 122 extends along one diagonal line of the base 101.
(2) Leads 104 are provided near two opposite corners on the other diagonal line of the base 101.
(3) On the lower surface of the base 101, notches 102 are provided near both of the corners in which the leads 104 are provided.

The semiconductor light-emitting element 150 according to Embodiment 3 has its semiconductor laser chip 122 disposed along a diagonal line of the base 101; therefore, in comparison with the semiconductor light-emitting element 100, a semiconductor laser chip 122 whose resonator is relatively long can be mounted over the base 101. This makes it possible to further increase a laser output from a semiconductor light-emitting element of an identical outer size.

Further, it is needless to say that in the semiconductor light-emitting device 200 or 250 described in Embodiment 1, the semiconductor light-emitting element 100 can be replaced by a semiconductor light-emitting element 150 according to Embodiment 3. Such a semiconductor light-emitting device is too encompassed in an embodiment of the present disclosure. Similarly, in the semiconductor light-emitting elements 300 described in Embodiment 2, too, the semiconductor light-emitting elements 100 can be replaced by semiconductor light-emitting elements 150 according to Embodiment 3, and such a semiconductor light-emitting device is too encompassed in an embodiment of the present disclosure.

The present disclosure is not limited to the aforementioned embodiments, but may be altered in various ways within the scope of the claims. An embodiment based on a proper combination of technical means disclosed in different embodiments is encompassed in the technical scope of the present disclosure.

The present disclosure contains subject matter related to that disclosed in Japanese Priority Patent Application JP 2017-200535 filed in the Japan Patent Office on Oct. 16, 2017, the entire contents of which are hereby incorporated by reference.

What is claimed is:

1. A semiconductor light-emitting element comprising:
a base made of a metal plate;
a cap, mounted on the base, that has a window made of an optically transparent member;
a semiconductor laser chip mounted over an upper surface of the base; and
a lead for supplying electric power to the semiconductor laser chip,
wherein the base has a notch provided in a region of a bottom surface thereof,
the lead is disposed so as to extend vertically through the base in the region of the base where the notch is provided,
the semiconductor laser chip is mounted over a region of the base that is free from the notch,
a lower end of the lead is located above the bottom surface of the base, and
an upper end of the lead and the semiconductor laser chip are housed in an internal space surrounded by the cap and the base.

2. The semiconductor light-emitting element according to claim 1, further comprising a mirror, placed over the upper surface of the base, that receives a laser beam emitted from the semiconductor laser chip, reflects the laser beam upward, and causes the laser beam to be outputted through the window,
wherein the semiconductor laser chip is disposed so that its waveguide longitudinal direction is substantially parallel to the upper surface of the base.

3. The semiconductor light-emitting element according to claim 1, wherein when seen in a plan view, the lower end of the lead is located inner than an outer edge of the base.

4. The semiconductor light-emitting element according to claim 1, wherein the notch is provided along one side surface of the base, and
a plurality of the leads are arranged along a side corresponding the side surface.

5. The semiconductor light-emitting element according to claim 1, wherein the base has a substantially quadrangular shape when seen in a plan view,
the semiconductor laser chip is placed so that its waveguide longitudinal direction extends along one diagonal line of the base,
the lead comprises leads provided near two opposite corners of another diagonal line of the base, and
the notch comprises notches provided near both of the corners in which the leads are provided.

6. A semiconductor light-emitting device comprising:
a heat sink; and
a semiconductor light-emitting element mounted on the heat sink,
wherein the semiconductor light-emitting element is the semiconductor light-emitting element according to claim 1.

7. The semiconductor light-emitting device according to claim 6, wherein the heat sink has a step, and
the semiconductor light-emitting element is mounted so that a side surface of the base that is free from the notch is in contact with a side surface of the step.

8. The semiconductor light-emitting device according to claim 6, wherein the semiconductor light-emitting element comprises a plurality of semiconductor light-emitting elements,
the plurality of semiconductor light-emitting elements are arranged in a line or a matrix on the heat sink,
the semiconductor light-emitting elements arranged in the line or an identical line of the matrix are arranged so that the notches are aligned in a straight line, and
in a space formed by the notches aligned in a straight line, a wiring member for supplying electric power to the line of semiconductor light-emitting elements is housed.
